(19) United States
(12) Patent Application Publication
(10) Pub. No.: US 2026/0305220 A1
(43) Pub. Date: Oct. 1, 2026

(54) METHOD FOR CLEANING SEMICONDUCTOR CHIP, AND METHOD FOR MANUFACTURING SEMICONDUCTOR DEVICE

(71) Applicant: Resonac Corporation, Minato-ku, Tokyo (JP)

(72) Inventors: Tatsuya MAKINO, Tokyo (JP); Hiroyoshi DEGUCHI, Tokyo (JP); Seiji KAI, Tokyo (JP); Toshiaki SHIRASAKA, Tokyo (JP); Tomohito MOROSAKI, Tokyo (JP); Chikashi AOYAGI, Tokyo (JP); Kazuhiro SASAKI, Tokyo (JP); Takehiro KINOSHITA, Tokyo (JP); Koji NAODA, Tokyo (JP)

(21) Appl. No.: 19/478,866

(22) PCT Filed: Apr. 25, 2024
(86) PCT No.: PCT/JP2024/016315

§ 371 Date: Oct. 27, 2025

(30) Foreign Application Priority Data
May 1, 2023 (JP) 2023-075733

(51) Int. Cl. H10P 70/00; H10P 54/40; H10P 54/92; H10P 58/00; H10P 72/70; H10W 80/00

(52) U.S. Cl. CPC H10P 70/30; H10P 58/22; H10P 72/7402; H10W 80/016; H10P 54/40; H10P 54/92

(57) ABSTRACT

A method for cleaning semiconductor chips includes (a) cleaning, with a chemical solution, a plurality of semiconductor chips disposed in a region on a surface of an adhesive film, the region being within a dicing ring attached on the surface, and (b) picking up the semiconductor chips from the surface after the cleaning. The adhesive film includes a base film and an adhesive layer formed on a surface of the base film. The adhesive layer contains an adhesive composition including a predetermined resin (A) and a photopolymerization initiator (B). The chemical solution is one type of chemical solution selected from the group consisting of solvent-based, acid-based, and alkali-based chemical solutions.

### TECHNICAL FIELD

The present disclosure relates to a method for cleaning semiconductor chips and a method for manufacturing a semiconductor device.

### BACKGROUND ART

Conventionally, a semiconductor device is manufactured through the following steps. That is, a semiconductor wafer is attached to a dicing adhesive sheet, and in that state, the semiconductor wafer is singulated into semiconductor chips (dicing step). Thereafter, picking up the semiconductor chips, bonding the semiconductor chips to an adherend (for example, a substrate), and the like are performed. With the increasing functionality of various devices, stacked MCPs (Multi Chip Packages), which have increased capacity by stacking semiconductor elements in multiple stages, have become widespread. In order to realize more advanced three-dimensional integration technology, for example, hybrid bonding for connecting different types of devices has also been developed. Patent Literature 1 discloses bonding a plurality of semiconductor chips to a substrate by hybrid bonding.

### CITATION LIST

### Patent Literature

Patent Literature 1: JP 2001-197431 A

### SUMMARY OF INVENTION

### Technical Problem

As a result of studies from various viewpoints toward the practical application of advanced three-dimensional integration technologies such as hybrid bonding, the present inventors have found that it is useful to clean semiconductor chips to a higher degree than in the past, prior to bonding the semiconductor chips to an adherend. In the manufacturing process of a semiconductor device, for example, foreign matter such as cutting debris may be generated in thinning a semiconductor wafer and a dicing step, and semiconductor chips to which such foreign matter is attached may be subjected to the next step. For example, in hybrid bonding, different types of devices are often bonded to each other face-to-face, and if foreign matter remains between the two faces, the connection reliability of the semiconductor device may be reduced even if the foreign matter is minute.

The present disclosure provides a method for cleaning semiconductor chips that can efficiently remove foreign matter attached to the semiconductor chips to a high degree in a manufacturing process of a semiconductor device. The present disclosure also provides a method for manufacturing a semiconductor device using the semiconductor chips cleaned by this method.

### Solution to Problem

One aspect of the present disclosure relates to a method for cleaning semiconductor chips. This method includes (a) cleaning, with a chemical solution, a plurality of semiconductor chips disposed in a region on a surface of an adhesive film, the region being within a dicing ring attached on the surface, and (b) picking up the semiconductor chips from the surface after the cleaning. The adhesive film includes a base film and an adhesive layer formed on a surface of the base film. The adhesive layer contains an adhesive composition including a resin (A) represented by formula (1-1) and a photopolymerization initiator (B). The chemical solution is one type of chemical solution selected from the group consisting of solvent-based, acid-based, and alkali-based chemical solutions.

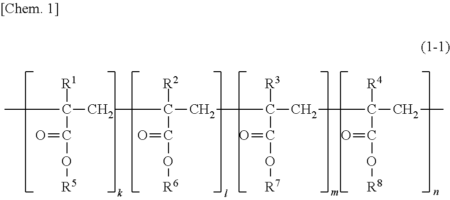

[In formula (1-1), k, 1, m, and n represent a molar composition ratio when k+1+m+n=100. k is more than 0 and 92 or less. 1 is 0 to 50. m is more than 0 and 90 or less. The total of k, 1, and m is 65 to 95. n is 5 to 35. R¹, R², R³, and R⁴ are a hydrogen atom or a methyl group. R⁵ is an alkyl group having 1 to 16 carbon atoms. R⁶ is an alicyclic hydrocarbon group having 3 to 30 carbon atoms or an aromatic hydrocarbon group having 6 to 20 carbon atoms. R⁷ is a hydrogen atom or —(CH₂)ⱼ—COOH (wherein j is 1 or 2). R⁸ is a group represented by formula (1-2) or formula (1-3).]

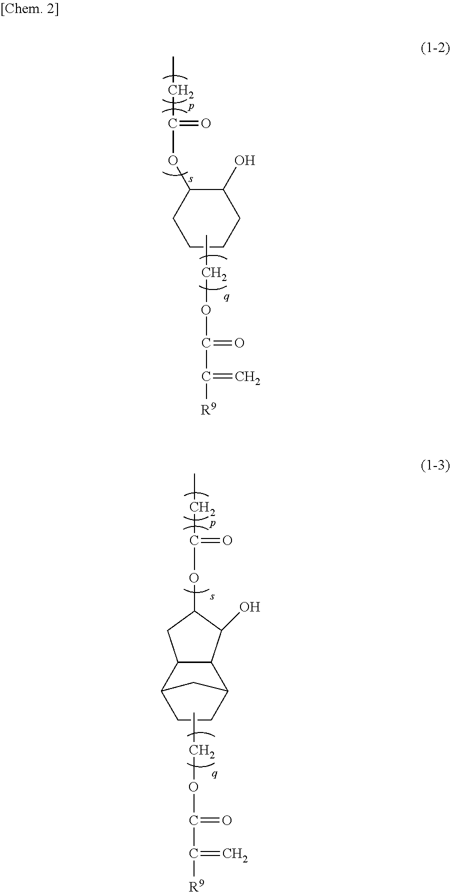

[In formula (1-2) and formula (1-3), p and q are an integer from 0 to 2. s is 0 when p is 0, and s is 1 when p is 1 or 2. R⁹ is a hydrogen atom or a methyl group.]

Conventionally, although semiconductor chips may be cleaned using water on the surface of an adhesive film to which a dicing ring is attached (also referred to as a “dicing tape”), the semiconductor chips have not been cleaned using a chemical solution. That is, for example, when bonding semiconductor chips to a substrate via bumps formed on the semiconductor chips, cleaning with water has not caused any problems. In contrast, according to the present invention, by cleaning the semiconductor chips on the adhesive film with a chemical solution, it is possible to remove foreign matter that has attached to the semiconductor chips to a high degree through various preceding steps. By using highly cleaned semiconductor chips, excellent connection reliability can be achieved for semiconductor devices manufactured by applying advanced three-dimensional integration technology.

Furthermore, according to studies by the present inventors, it was found that a predetermined resin included in the above-mentioned adhesive composition has resistance to chemical solutions and its adhesive force is unlikely to decrease. Therefore, according to the present invention, it is possible to prevent the semiconductor chips from detaching from the surface of the adhesive film during the process of cleaning the semiconductor chips with a chemical solution.

The above-described cleaning method is also useful in that it can be efficiently performed in a semiconductor manufacturing process. That is, in the manufacturing process of a semiconductor device, it is not efficient to transport semiconductor chips to equipment for highly cleaning the semiconductor chips, and then return the cleaned semiconductor chips to mounting equipment. In contrast, according to the present invention, since the high-level cleaning with a chemical solution is performed on the surface of the adhesive film and in a state where the dicing ring is attached to the adhesive film, the cleaned semiconductor chips can be picked up and directly subjected to the next step.

One aspect of the present disclosure relates to a method for manufacturing a semiconductor device. This method includes bonding, to an adherend, semiconductor chips that have been subjected to the above-described method for cleaning semiconductor chips. According to this method, since highly cleaned semiconductor chips are used, it is possible to manufacture a semiconductor device having excellent connection reliability.

### Advantageous Effects of Invention

According to the present disclosure, a method for cleaning semiconductor chips is provided that can efficiently remove foreign matter attached to the semiconductor chips to a high degree in a manufacturing process of a semiconductor device. Furthermore, according to the present disclosure, a method for manufacturing a semiconductor device is provided that uses semiconductor chips cleaned by this method.

### BRIEF DESCRIPTION OF DRAWINGS

FIG. 1 is a cross-sectional view schematically showing a state in which preparations for performing the cleaning method according to the present disclosure are complete.

FIG. 2 is a cross-sectional view schematically showing a state in which a semiconductor chip is being picked up after cleaning.

FIG. 3(a), FIG. 3(b), and FIG. 3(c) are cross-sectional views schematically showing a process of manufacturing a semiconductor device by a method according to a first embodiment.

FIG. 4(a), FIG. 4(b), and FIG. 4(c) are cross-sectional views schematically showing a process of manufacturing a semiconductor device by a method according to the first embodiment.

FIG. 5 is a cross-sectional view schematically showing a state in which the interval between two adjacent semiconductor chips is widened by applying tension to an adhesive film.

FIG. 6 is a cross-sectional view schematically showing a state in which one semiconductor chip is bonded on a substrate.

FIG. 7 is a cross-sectional view schematically showing a state in which a plurality of semiconductor chips are stacked on a substrate.

FIG. 8 is a cross-sectional view schematically showing an example of a semiconductor device having a configuration in which a plurality of semiconductor chips are stacked.

FIG. 9(a) and FIG. 9(b) are cross-sectional views schematically showing a process of manufacturing a semiconductor device by a method according to a second embodiment.

FIG. 10(a) and FIG. 10(b) are cross-sectional views schematically showing a process of manufacturing a semiconductor device by a method according to the second embodiment.

FIG. 11(a) and FIG. 11(b) are cross-sectional views schematically showing a process of manufacturing a semiconductor device by a method according to a third embodiment.

FIG. 12(a) and FIG. 12(b) are cross-sectional views schematically showing a process of manufacturing a semiconductor device by a method according to the third embodiment.

FIG. 13(a) and FIG. 13(b) are cross-sectional views schematically showing a process of manufacturing a semiconductor device by a method according to a fourth embodiment.

FIG. 14(a), FIG. 14(b), and FIG. 14(c) are cross-sectional views schematically showing a process of manufacturing a semiconductor device by a method according to a fifth embodiment.

### DESCRIPTION OF EMBODIMENTS

Hereinafter, embodiments of the present disclosure will be described in detail with reference to the drawings. However, the present disclosure is not limited to the following embodiments. In the following embodiments, their constituent elements (including steps and the like) are not essential unless otherwise specified. In the following description, the same or corresponding parts are denoted by the same reference signs, and redundant description will be omitted. In addition, positional relationships such as up, down, left, and right shall be based on the positional relationships shown in the drawings, unless otherwise specified. The size of the constituent elements in each drawing is conceptual, and the dimensional ratios in the drawings are not limited to the illustrated ratios.

Numerical values and their ranges in this specification also do not limit the present disclosure. In this specification, a numerical range indicated using “to” indicates a range including the numerical values described before and after “to” as the minimum value and the maximum value, respectively. In numerical ranges described stepwise in this specification, an upper limit value or a lower limit value described in one numerical range may be replaced with an upper limit value or a lower limit value of another stepwise described numerical range.

### <Method for Cleaning Semiconductor Chips>

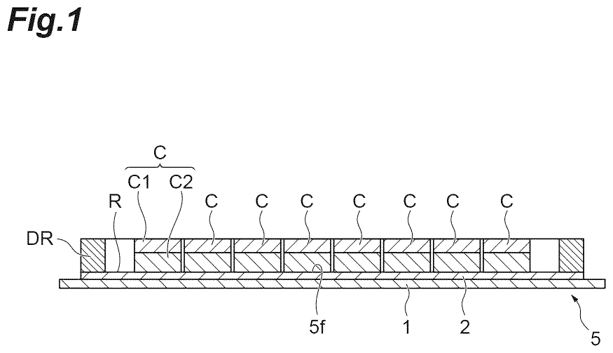

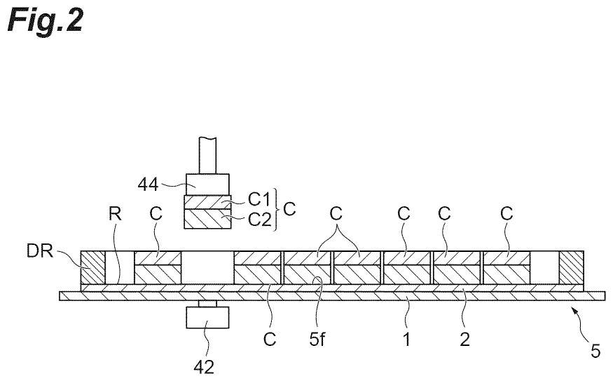

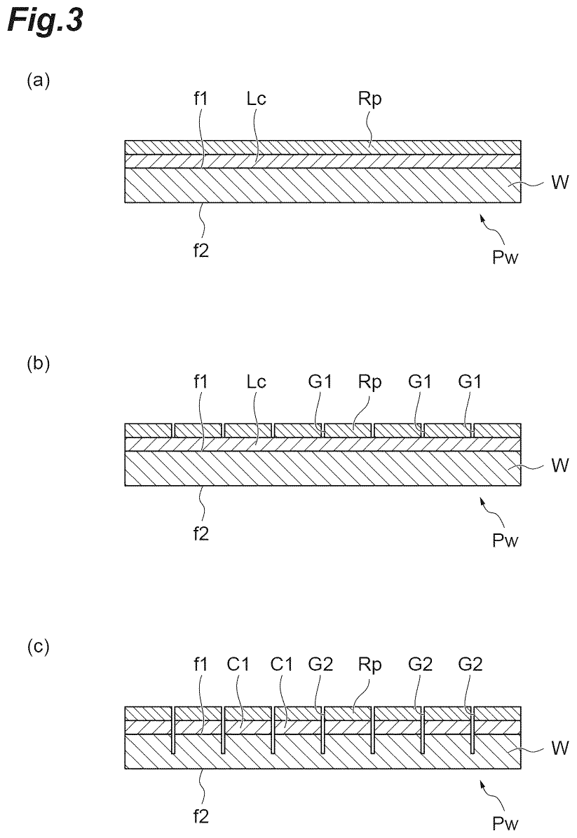

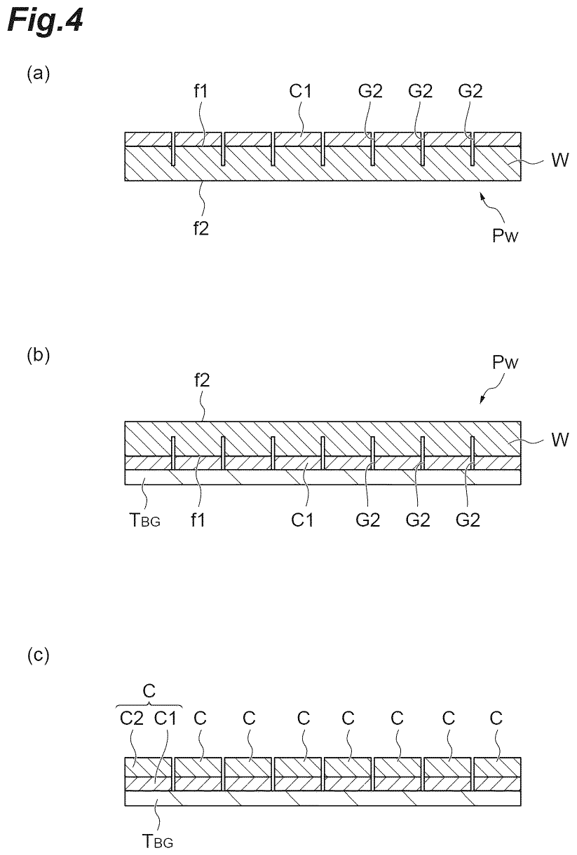

A method for cleaning semiconductor chips according to the present embodiment will be described with reference to FIGS. 1 and 2. FIG. 1 is a cross-sectional view schematically showing a state in which preparations for performing the cleaning method according to the present embodiment are complete. A plurality of semiconductor chips C shown in FIG. 1 are the objects to be cleaned. FIG. 2 is a cross-sectional view schematically showing a state in which a semiconductor chip C is being picked up after cleaning. The semiconductor chip C is obtained through singulating a workpiece Pw shown in FIG. 3(a), and includes a circuit layer C1 and a die C2. The circuit layer C1 is a singulated circuit layer Lc, and the die C2 is a singulated semiconductor wafer W (see FIG. 4(c)).

The cleaning method according to the present embodiment includes the following steps.
(a) Cleaning, with a chemical solution, a plurality of semiconductor chips C disposed in a region R on a surface 5f of an adhesive film 5, the region being within a dicing ring DR attached on the surface 5f.
(b) Picking up the semiconductor chips C from the surface after the cleaning.

As shown in FIG. 1, a plurality of semiconductor chips C are disposed in a region R surrounded by a dicing ring DR. A specific method for cleaning the semiconductor chips C is not particularly limited, but for example, the semiconductor chips C are cleaned by spraying a chemical solution from a nozzle toward the semiconductor chips C. The chemical solution is, for example, one type of chemical solution selected from the group consisting of solvent-based, acid-based, and alkali-based chemical solutions.

The solvent-based chemical solution contains, for example, NMP (N-methyl-2-pyrrolidone), MEK (methyl ethyl ketone), PGMEA (propylene glycol monomethyl ether acetate), DMSO (dimethyl sulfoxide), or cyclopentanone, and can remove foreign matter such as cutting debris, grinding debris, processing debris, and dust from the semiconductor chips C to a high degree.

The acid-based chemical solution contains, for example, sulfuric acid, citric acid, or hydrofluoric acid, and can remove foreign matter such as cutting debris, grinding debris, processing debris, and dust from the semiconductor chips C to a high degree.

The alkali-based chemical solution contains, for example, potassium hydroxide, sodium hydroxide, ammonium hydroxide, sodium bicarbonate, hydroxylamine, TMAH (tetramethylammonium hydroxide), or aqueous ammonia, and can remove foreign matter such as cutting debris, grinding debris, processing debris, and dust from the semiconductor chips C to a high degree.

The adhesive film 5 includes a base film 1 and an adhesive layer 2 formed on a surface of the base film 1. Examples of the base film 1 include plastic films such as a polytetrafluoroethylene film, a polyethylene terephthalate film, a polyethylene film, a polypropylene film, a polymethylpentene film, and a polyimide film. Among these, a film having resistance to the chemical solution used for cleaning the semiconductor chips C may be used. If necessary, a surface treatment such as primer application, UV treatment, corona discharge treatment, polishing treatment, or etching treatment may be performed.

The adhesive layer 2 contains an adhesive composition including a resin (A) represented by formula (1-1) and a photopolymerization initiator (B). The adhesive composition can have resistance to the chemical solution used for cleaning the semiconductor chips C. The adhesive layer 2 is formed by applying a coating liquid containing the adhesive composition to the surface of the base film 1, or by a process including steps of producing a film made of the adhesive composition using a coating liquid containing the adhesive composition, and attaching the film to the surface of the base film 1. The adhesive layer 2 can have a property of decreasing in adhesive force when irradiated with activation energy (for example, ultraviolet rays (UV)).

The resin (A) is a compound (resin) represented by formula (1-1).

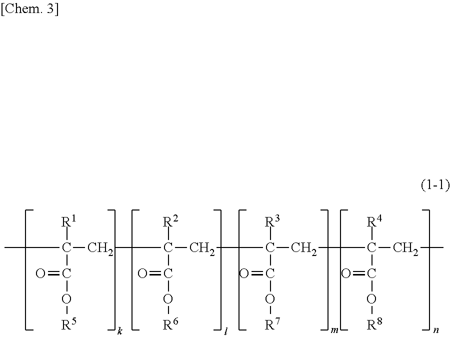

In formula (1-1), k, 1, m, and n represent a molar composition ratio when k+1+m+n=100. k is more than 0 and 92 or less. 1 is 0 to 50. m is more than 0 and 90 or less. The total of k, 1, and m is 65 to 95. n is 5 to 35. R¹, R², R³, and R⁴ are a hydrogen atom or a methyl group. R⁵ is an alkyl group having 1 to 16 carbon atoms. R⁶ is an alicyclic hydrocarbon group having 3 to 30 carbon atoms or an aromatic hydrocarbon group having 6 to 20 carbon atoms. R⁷ is a hydrogen atom or —(CH₂)ⱼ—COOH (wherein j is 1 or 2). R⁸ is a group represented by formula (1-2) or formula (1-3).

When the total of k, 1, and m is 65 or more, an adhesive composition that provides sufficient adhesiveness to an adherend before activation energy irradiation is obtained. The total of k, 1, and m is preferably 70 to 94, and more preferably 80 to 90.

In formula (1-1), the structural unit in the parenthesis of k (hereinafter, referred to as “structural unit k”) is an essential structural unit. The structural unit k contributes to the adhesive force of the adhesive composition before activation energy irradiation. The number of structural units of the structural unit k is more than 0 and 92 or less, preferably 45 to 90, and more preferably 60 to 88.

In formula (1-1), the structural unit in the parenthesis of 1 (hereinafter, referred to as “structural unit 1”) is not necessarily an essential structural unit. In other words, the number of structural units of the structural unit 1 may be 0.

The structural unit 1 contributes to the heat resistance of the adhesive composition. The number of structural units of the structural unit 1 is 0 to 50, preferably 4 to 40, and more preferably 5 to 30.

In formula (1-1), the structural unit in the parenthesis of m (hereinafter, referred to as “structural unit m”) is an essential structural unit. The structural unit m contributes to the adhesive force and heat resistance of the adhesive composition before activation energy irradiation. In addition, when the adhesive composition includes a cross-linking agent having a functional group that reacts with a carboxy group, the structural unit m reacts with the cross-linking agent to improve the cohesive force of the adhesive composition. The number of structural units m of the structural unit m is more than 0 and 90 or less, preferably 1 to 15, and more preferably 1 to 5.

In formula (1-1), the structural unit in the parenthesis of n (hereinafter, referred to as “structural unit n”) is an essential structural unit. The structural unit n contributes to the heat resistance of the adhesive composition. The number of structural units n of the structural unit n is 5 to 35, preferably 10 to 33, and more preferably 10 to 20. When the structural unit n is 35 or less, an adhesive composition is obtained in which, by irradiating with activation energy, the unsaturated bonds in the resin (A) form a three-dimensional cross-linked structure and cure, and the adhesive force decreases to an appropriate range. In addition, when n is 5 or more, a heat resistance improving effect due to the structure derived from the alicyclic compound is obtained.

Due to the synergistic effect of the functions contributed by each of these structural units, the adhesive composition including the resin (A) has an even better balance between the adhesive force before activation energy irradiation and the adhesive force after activation energy irradiation. As a result, an adhesive composition is obtained that provides sufficient adhesive force to an adherend before activation energy irradiation, and has a reduced adhesive force and excellent easy peelability after activation energy irradiation. Moreover, this adhesive composition does not have an excessively high adhesive force even when it is brought to a high temperature state and then returned to room temperature before activation energy irradiation, provides excellent easy peelability after activation energy irradiation, and is less likely to cause adhesive residue on the adherend after peeling.

In the structural unit k, R¹ is a hydrogen atom (—H) or a methyl group (—CH₃), and is preferably a hydrogen atom (—H). R⁵ is an alkyl group having 1 to 16 carbon atoms, preferably an alkyl group having 1 to 8 carbon atoms, and more preferably an alkyl group having 2, 4, or 8 carbon atoms.

The structural unit k may be a plurality of types of structural units with different R¹ and R⁵. When the structural unit k includes a plurality of types of structural units, the molar composition ratio of the structural unit k indicates the sum of the molar composition ratios of the plurality of types of structural units. For example, when the structural unit k includes structural units A and B with different R¹ and/or R⁵, and the molar composition ratio of structural unit Ais 2 mol % and the molar composition ratio of structural unit B is 3 mol %, the molar composition ratio of the number of structural units k is “5” by summing the molar composition ratios of structural unit A and structural unit B.

In the structural unit 1, R² is a hydrogen atom (—H) or a methyl group (—CH₃), and is preferably a hydrogen atom (—H). R⁶ is an alicyclic hydrocarbon group having 3 to 30 carbon atoms or an aromatic hydrocarbon group having 6 to 20 carbon atoms, and is preferably an alicyclic hydrocarbon group having 6 to 20 carbon atoms or an aromatic hydrocarbon group having 6 to 10 carbon atoms.

The structural unit 1 may be a plurality of types of structural units with different R² and R⁶. When the structural unit 1 includes a plurality of types of structural units, the molar composition ratio of the structural unit 1 indicates the sum of the molar composition ratios of the plurality of types of structural units.

In the structural unit m, R³ is a hydrogen atom (—H) or a methyl group (—CH₃), and is preferably a hydrogen atom (—H). R⁷ is a hydrogen atom (—H) or —(CH₂)ⱼ—COOH (wherein j is 1 or 2), and is preferably a hydrogen atom (—H).

The structural unit m may be a plurality of types of structural units with different R³ and R⁷. In this case, the molar composition ratio of the structural unit m indicates the sum of the molar composition ratios of the plurality of types of structural units.

In the structural unit n, R⁴ is a hydrogen atom (—H) or a methyl group (—CH₃), and is preferably a hydrogen atom (—H). R⁸ is a group represented by formula (1-2) or formula (1-3). The groups represented by formula (1-2) or formula (1-3) both include a structure derived from an alicyclic compound and have a function of improving the heat resistance of the adhesive composition.

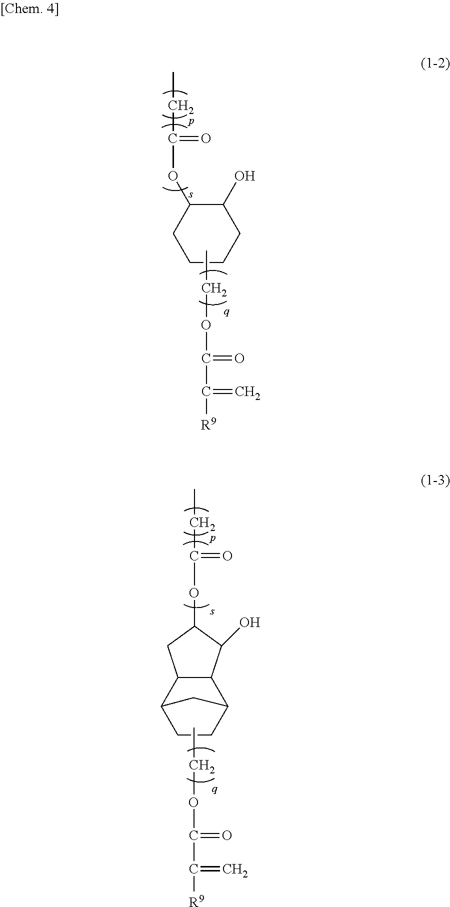

In formula (1-2) and formula (1-3), p and q are an integer from 0 to 2. s is 0 when p is 0, and s is 1 when p is 1 or 2. R⁹ is a hydrogen atom or a methyl group.

The structural unit n may be a plurality of types of structural units with different R⁴ and R⁸. In this case, the molar composition ratio of the structural unit n indicates the sum of the molar composition ratios of the plurality of types of structural units.

The resin (A) represented by formula (1-1) may be any of a random copolymer, a block copolymer, or an alternating copolymer consisting of the structural unit k, the structural unit 1, the structural unit m, and the structural unit n. The resin (A) represented by formula (1-1) may not include the structural unit 1, and may be any of a random copolymer, a block copolymer, or an alternating copolymer consisting of the structural unit k, the structural unit m, and the structural unit n.

The weight-average molecular weight (Mw) of the resin (A) is preferably 200,000 to 1,000,000, and more preferably 300,000 to 800,000. When the weight-average molecular weight of the resin (A) is 200,000 or more, the adhesive layer is even less likely to remain on the adherend when peeled off after the adhesive layer containing the adhesive composition is attached to the adherend. When the weight-average molecular weight of the resin (A) is 1,000,000 or less, the viscosity of the resin (A) does not become too high, and an effect of favorable workability is obtained. The weight-average molecular weight of the resin (A) means a value measured by gel permeation chromatography (GPC) and converted using a calibration curve based on standard polystyrene, and can be measured, for example, with the following apparatus and under the following conditions.

Measured at room temperature (25° C.) using gel permeation chromatography (Shodex (registered trademark) GPC-101, manufactured by Resonac Corporation) and calculated in terms of polystyrene.
Column: Shodex (registered trademark) LF-804, manufactured by Resonac Corporation
Column temperature: 40° C.
Sample: 0.2 mass % tetrahydrofuran solution of resin (A)
Flow rate: 1 ml/min
Eluent: Tetrahydrofuran
Detector: RI detector

The glass transition temperature (Tg) of the resin (A) is preferably −80 to 0° C., more preferably −60 to −10° C., and still more preferably −50 to −10° C. When the glass transition temperature of the resin (A) is in the range of −80° C. to 0° C., the adhesive force of the adhesive composition before activation energy irradiation becomes sufficient. The Tg of the resin (A) means a value measured by the method described below. First, a 10 mg sample is taken from the resin (A). Next, using a differential scanning calorimeter (DSC), differential scanning calorimetry is performed by changing the temperature of the sample from −100° C. to 200° C. at a heating rate of 10° C./min, and the endothermic onset temperature due to the observed glass transition is taken as the Tg. If two Tgs are observed, the simple average of the two Tgs is taken as the Tg.

The acid value of the resin (A) is preferably more than 0 and 20 mgKOH/g or less, and more preferably 3 to 10 mgKOH/g. When the acid value of the resin (A) is in the range of more than 0 and 20 mgKOH/g or less, contamination of the adherend (adhesive residue) after heating is absent, which is preferable. In addition, when the adhesive composition includes a cross-linking agent, if the acid value of the resin (A) is within the above range, the resin (A) and the cross-linking agent react, and the cohesive force of the adhesive composition becomes sufficient. The acid value of the resin (A) means a value measured according to JIS K0070: 1992.

The resin (A) can be manufactured, for example, by the method shown below. First, a raw material monomer including a carboxy group-containing ethylenically unsaturated monomer (a) and an ethylenically unsaturated monomer (d) is polymerized to manufacture a carboxy group-containing resin (b). Here, the ethylenically unsaturated monomer (d) may include a monomer that provides the structural unit k and a monomer that provides the structural unit 1 after polymerization. Next, the resin (A) can be manufactured by an addition reaction of the carboxy group-containing resin (b) and a specific alicyclic epoxy group-containing ethylenically unsaturated compound (c).

The carboxy group-containing ethylenically unsaturated monomer (a) is a monomer that provides the structural unit m by polymerization. The carboxy group-containing ethylenically unsaturated monomer (a) has one carboxy group.

Examples of the carboxy group-containing ethylenically unsaturated monomer (a) include (meth)acrylic acid, β-carboxyethyl (meth)acrylate, carboxypentyl (meth)acrylate, and the like. Among these, as the carboxy group-containing ethylenically unsaturated monomer (a), it is preferable to use (meth)acrylic acid and/or β-carboxyethyl (meth)acrylate from the viewpoint of reactivity.

In this specification, “(meth)acryl” means “acryl” or “methacryl”. “(Meth)acrylate” means “acrylate” or “methacrylate”. The same applies to other similar expressions.

The carboxy group-containing resin (b) is obtained by copolymerizing a raw material monomer including at least a carboxy group-containing ethylenically unsaturated monomer (a) and an ethylenically unsaturated monomer (d) copolymerizable with the carboxy group-containing ethylenically unsaturated monomer (a).

The carboxy group-containing resin (b) is a component that constitutes the main skeleton of the resin (A) represented by formula (1-1). The structural unit k, the structural unit 1, and the structural unit m are all structural units derived from the carboxy group-containing resin (b).

As the ethylenically unsaturated monomer (d), one or more types of monomers that provide the structural unit k by polymerization are used. As the ethylenically unsaturated monomer (d), one or more types of monomers that provide the structural unit 1 by polymerization may be used together with the monomer that provides the structural unit k by polymerization.

The ethylenically unsaturated monomer (d) that provides the structural unit k by polymerization is an alkyl (meth)acrylate having 1 to 16 carbon atoms, and from the viewpoint of adjusting the peel strength of the adhesive composition, it preferably includes an alkyl (meth)acrylate having 2 to 16 carbon atoms, and more preferably includes an alkyl (meth)acrylate having 4 to 12 carbon atoms. Specific examples include methyl(meth)acrylate, ethyl (meth)acrylate, n-propyl(meth)acrylate, n-butyl (meth)acrylate, tert-butyl (meth)acrylate, isobutyl (meth)acrylate, 2-ethylhexyl(meth)acrylate, isodecyl (meth)acrylate, n-hexyl (meth)acrylate, isooctyl (meth)acrylate, lauryl (meth)acrylate, and the like. Among these, methyl(meth)acrylate, ethyl (meth)acrylate, n-butyl (meth)acrylate, 2-ethylhexyl(meth)acrylate, or isooctyl (meth)acrylate is preferable.

Examples of the ethylenically unsaturated monomer (d) that provides the structural unit 1 by polymerization include a cyclic alkyl group-containing (meth)acrylate having 3 to 30 carbon atoms, an aromatic group-containing (meth)acrylate having 6 to 20 carbon atoms, and the like.

Examples of the cyclic alkyl group-containing (meth)acrylate having 3 to 30 carbon atoms used as the ethylenically unsaturated monomer (d) that provides the structural unit 1 by polymerization include cyclohexyl(meth)acrylate, norbornyl (meth)acrylate, isobornyl (meth)acrylate, norbornanyl (meth)acrylate, dicyclopentenyl (meth)acrylate, dicyclopentenyloxyethyl (meth)acrylate, dicyclopentanyl (meth)acrylate, dicyclopentanyloxyethyl (meth)acrylate, tricyclodecane dimethylol di(meth)acrylate, and the like. Among these, it is particularly preferable to use isobornyl (meth)acrylate. When the raw material monomer of the carboxy group-containing resin (b) includes a cyclic alkyl (meth)acrylate, the heat resistance of the adhesive composition including the resin (A) manufactured using the carboxy group-containing resin (b) is improved.

Examples of the aromatic group-containing (meth)acrylate having 6 to 20 carbon atoms used as the ethylenically unsaturated monomer (d) that provides the structural unit 1 by polymerization include benzyl (meth)acrylate, phenoxyethyl (meth)acrylate, phenoxypolyethylene glycol (meth)acrylate, phenoxypropyl(meth)acrylate, phenoxypolypropylene glycol (meth)acrylate, and the like. Among these, it is particularly preferable to use benzyl (meth)acrylate. When the carboxy group-containing resin (b) includes an aromatic group-containing (meth)acrylate as a raw material monomer, the heat resistance of the adhesive composition including the resin (A) manufactured using the carboxy group-containing resin (b) is improved.

The raw material monomer of the carboxy group-containing resin (b) may include, in addition to the carboxy group-containing ethylenically unsaturated monomer (a) and the ethylenically unsaturated monomer (d), a monomer copolymerizable with the carboxy group-containing ethylenically unsaturated monomer (a), other than the ethylenically unsaturated monomer (d).

Examples of the ethylenically unsaturated monomer copolymerizable with the carboxy group-containing ethylenically unsaturated monomer (a), other than the ethylenically unsaturated monomer (d), include alkoxyalkyl (meth)acrylates, alkoxy (poly)alkylene glycol (meth)acrylates, hydroxy group-containing (meth)acrylates, fluorinated alkyl (meth)acrylates, dialkylaminoalkyl (meth)acrylates, (meth)acrylamide, and the like.

Examples of the alkoxyalkyl (meth)acrylate include ethoxyethyl (meth)acrylate, methoxyethyl (meth)acrylate, butoxyethyl (meth)acrylate, 2-methoxyethoxyethyl (meth)acrylate, 2-ethoxyethoxyethyl (meth)acrylate, and the like.

Examples of the alkoxy (poly)alkylene glycol (meth)acrylate include methoxydiethylene glycol (meth)acrylate, ethoxydiethylene glycol (meth)acrylate, methoxydipropylene glycol (meth)acrylate, and the like.

Examples of the hydroxy group-containing (meth)acrylate include 2-hydroxyethyl (meth)acrylate, 2-hydroxypropyl(meth)acrylate, 4-hydroxybutyl (meth)acrylate, 1,3-butanediol (meth)acrylate, 1,4-butanediol (meth)acrylate, 1,6-hexanediol (meth)acrylate, 3-methylpentanediol (meth)acrylate, and the like.

Examples of the fluorinated alkyl (meth)acrylate include octafluoropentyl (meth)acrylate and the like.

Examples of the dialkylaminoalkyl (meth)acrylate include N,N-dimethylaminoethyl (meth)acrylate, N,N-diethylaminoethyl (meth)acrylate, and the like.

Examples of the (meth)acrylamide include (meth)acrylamide, N-methyl(meth)acrylamide, N-ethyl (meth)acrylamide, N-propyl(meth)acrylamide, N-isopropylacrylamide, N-hexyl(meth)acrylamide, N,N-dimethyl(meth)acrylamide, N,N-diethyl(meth)acrylamide, (meth)acryloylmorpholine, diacetone acrylamide, and the like.

Specific examples of the monomer copolymerizable with the carboxy group-containing ethylenically unsaturated monomer (a), other than the ethylenically unsaturated monomer (d), include acrylonitrile, methacrylonitrile, styrene, α-methylstyrene, vinyl acetate, vinyl propionate, vinyl stearate, vinyl chloride, vinylidene chloride, alkyl vinyl ether, vinyltoluene, N-vinylpyridine, N-vinylpyrrolidone, dialkyl itaconate, dialkyl fumarate, allyl alcohol, hydroxybutyl vinyl ether, hydroxyethyl vinyl ether, 4-hydroxymethylcyclohexylmethyl vinyl ether, triethylene glycol monovinyl ether, diethylene glycol monovinyl ether, methyl vinyl ketone, allyltrimethylammonium chloride, dimethylallyl vinyl ketone, and the like.

The method for manufacturing the carboxy group-containing resin (b) is not particularly limited. For example, it can be obtained by copolymerizing a raw material monomer including the carboxy group-containing ethylenically unsaturated monomer (a) and the ethylenically unsaturated monomer (d), which are constituent components of the carboxy group-containing resin (b), by a known polymerization method.

Specifically, as the polymerization method, a solution polymerization method, an emulsion polymerization method, a bulk polymerization method, a suspension polymerization method, an alternating copolymerization method, or the like can be used. Among these polymerization methods, considering the addition reaction between the carboxy group-containing resin (b) obtained after polymerization and the alicyclic epoxy group-containing ethylenically unsaturated compound (c), it is preferable to use the solution polymerization method from the viewpoint of ease of reaction.

When manufacturing the carboxy group-containing resin (b) by the solution polymerization method, a radical polymerization initiator and/or a solvent is used as necessary.

The radical polymerization initiator is not particularly limited, and can be appropriately selected and used from known ones. Examples of the radical polymerization initiator include azo-based polymerization initiators such as 2,2′-azobis(isobutyronitrile), 2,2′-azobis(4-methoxy-2,4-dimethylvaleronitrile), 2,2′-azobis(2,4-dimethylvaleronitrile), 2,2′-azobis(2-methylbutyronitrile), 1,1′-azobis(cyclohexane-1-carbonitrile), 2,2′-azobis(2,4,4-trimethylpentane), and dimethyl-2,2′-azobis(2-methylpropionate); and oil-soluble polymerization initiators such as peroxide-based polymerization initiators including benzoyl peroxide, t-butyl hydroperoxide, di-t-butyl peroxide, t-butyl peroxybenzoate, dicumyl peroxide, 1,1-bis(t-butylperoxy)-3,3,5-trimethylcyclohexane, and 1,1-bis(t-butylperoxy)cyclododecane. These radical polymerization initiators may be used alone, or two or more kinds may be used in combination.

The amount of the radical polymerization initiator used is preferably 0.01 to 5 parts by mass, more preferably 0.02 to 4 parts by mass, and even more preferably 0.03 to 3 parts by mass, with respect to 100 parts by mass of the total raw material monomers of the carboxy group-containing resin (b).

As the polymerization solvent used when manufacturing the carboxy group-containing resin (b), various general solvents can be used. Examples of the solvent include esters such as ethyl acetate, n-propyl acetate, and n-butyl acetate; aromatic hydrocarbons such as toluene, xylene, and benzene; aliphatic hydrocarbons such as n-hexane and n-heptane; alicyclic hydrocarbons such as cyclohexane and methylcyclohexane; ketones such as methyl ethyl ketone and methyl isobutyl ketone; glycols such as ethylene glycol, propylene glycol, and dipropylene glycol; glycol ethers such as methyl cellosolve, propylene glycol monomethyl ether, and dipropylene glycol monomethyl ether; and glycol esters such as ethylene glycol diacetate and propylene glycol monomethyl ether acetate. These solvents may be used alone, or two or more kinds may be used in combination.

When manufacturing the carboxy group-containing resin (b), the content of the carboxy group-containing ethylenically unsaturated monomer (a) in the raw material monomer including the carboxy group-containing ethylenically unsaturated monomer (a), the ethylenically unsaturated monomer (d), and other monomers contained as necessary is preferably 5 to 40 mass %, more preferably 7 to 30 mass %, and even more preferably 10 to 25 mass %. By setting the content of the carboxy group-containing ethylenically unsaturated monomer (a) in the raw material monomer within the above range, the adhesive force of the adhesive layer obtained from the adhesive composition including the resin (A) manufactured by the addition reaction of the carboxy group-containing resin (b) and the alicyclic epoxy group-containing ethylenically unsaturated compound (c) becomes sufficient before activation energy irradiation.

The alicyclic epoxy group-containing ethylenically unsaturated compound (c) is an ethylenically unsaturated group-containing compound having an alicyclic epoxy group, and is a compound that provides a group represented by formula (1-2) or formula (1-3). Here, the alicyclic epoxy group means an epoxy group formed by one oxygen atom bonded to two adjacent carbon atoms on the ring of an alicyclic hydrocarbon compound.

The alicyclic epoxy group-containing ethylenically unsaturated compound (c) is used to add a group represented by formula (1-2′) or formula (1-3′), which is a partial structure in the structural unit n of the resin (A) represented by formula (1-1). The group represented by formula (1-2′) or formula (1-3′) in the structural unit n in formula (1-1) is a group derived from the alicyclic epoxy group-containing ethylenically unsaturated compound (c).

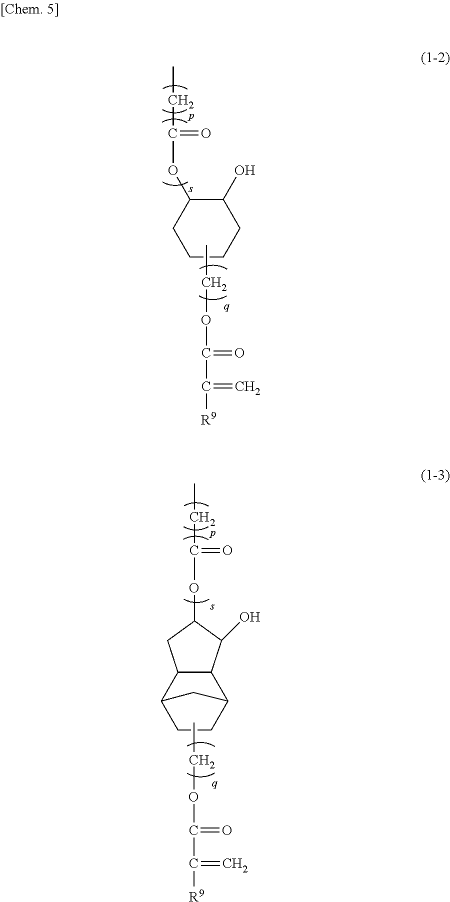

In formula (1-2′) and formula (1-3′), q is an integer from 0 to 2. R⁹ is a hydrogen atom or a methyl group.

Examples of the alicyclic epoxy group-containing ethylenically unsaturated compound (c) include compounds represented by formula (1) or formula (2).

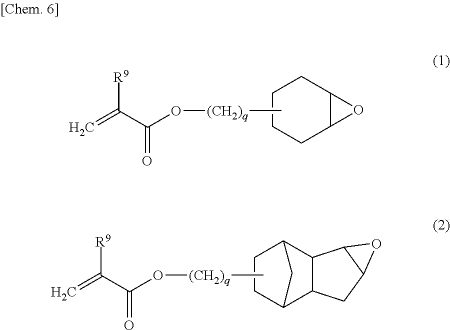

In formula (1), R⁹ is a hydrogen atom or a methyl group. q is an integer from 0 to 2. In formula (2), R⁹ is a hydrogen atom or a methyl group. q is an integer from 0 to 2.

In formula (1), R⁹ is a hydrogen atom (—H) or a methyl group (—CH₃). q is an integer from 0 to 2, and it is preferable that q is 1.

In formula (2), R⁹ is a hydrogen atom (—H) or a methyl group (—CH₃). q is an integer from 0 to 2, and it is preferable that q is 1.

As the alicyclic epoxy group-containing ethylenically unsaturated compound (c), a compound represented by formula (1) is preferable, and it is more preferable to use 3,4-epoxycyclohexylmethyl(meth)acrylate. The alicyclic epoxy group-containing ethylenically unsaturated compound (c) may be used alone as one kind, or two or more kinds may be used in combination.

The resin (A) can be manufactured by causing an addition reaction of the alicyclic epoxy group of the alicyclic epoxy group-containing ethylenically unsaturated monomer (c) to the carboxy group of the carboxy group-containing resin (b).

The resin (A) is preferably manufactured by causing an addition reaction of preferably 0.2 to 0.99 mol, more preferably 0.3 to 0.95 mol, and even more preferably 0.6 to 0.95 mol of the alicyclic epoxy group-containing ethylenically unsaturated compound (c) with respect to 1 mol of the carboxy group of the carboxy group-containing resin (b). An adhesive composition including the resin (A) obtained by using the carboxy group-containing resin (b) and the alicyclic epoxy group-containing ethylenically unsaturated compound (c) in the above ratio provides sufficient adhesiveness to an adherend before activation energy irradiation, and has a reduced adhesive force and more excellent easy peelability after activation energy irradiation. Moreover, this adhesive composition is less likely to have an increased adhesive force even when it is brought to a high temperature state and then returned to room temperature before activation energy irradiation, provides excellent easy peelability after activation energy irradiation, and can more effectively prevent adhesive residue on the adherend after peeling.

The temperature of the addition reaction when manufacturing the resin (A) is preferably 80 to 130° C., and more preferably 90 to 120° C. When the temperature of the addition reaction is 80° C. or higher, a sufficient reaction rate can be obtained. When the temperature of the addition reaction is 130° C. or lower, it is possible to prevent the double bond portion from cross-linking due to thermal radical polymerization and generating a gelled product.

In the addition reaction when manufacturing the resin (A), a known catalyst can be used as necessary. Examples of the catalyst include tertiary amines such as triethylamine, tributylamine, dimethylbenzylamine, 1,8-diazabicyclo [5,4,0]undec-7-ene, 1,5-diazabicyclo [4,3,0]non-5-ene, and 1,4-diazabicyclo [2,2,2]octane; quaternary ammonium salts such as tetramethylammonium chloride, tetramethylammonium bromide, and tetrabutylammonium bromide; alkyl ureas such as tetramethylurea; alkyl guanidines such as tetramethylguanidine; and phosphine compounds such as triphenylphosphine, dimethylphenylphosphine, tricyclohexylphosphine, tributylphosphine, tris(4-methylphenyl)phosphine, tris(4-methoxyphenyl)phosphine, tris(2,6-dimethylphenyl)phosphine, tris(2,6-dimethoxyphenyl)phosphine, tris(2,4,6-trimethylphenyl)phosphine, and tris(2,4,6-trimethoxyphenyl)phosphine. Among these, as the catalyst, it is preferable to use a phosphine compound from the viewpoint of reactivity.

The amount of the catalyst used in the addition reaction is preferably 0.01 to 30 parts by mass, more preferably 0.05 to 5 parts by mass, and even more preferably 0.1 to 2 parts by mass, with respect to 100 parts by mass of the total of the carboxy group-containing resin (b) and the alicyclic epoxy group-containing ethylenically unsaturated monomer (c).

Furthermore, during the addition reaction, a gas having a polymerization inhibiting effect may be introduced into the reaction system, or a polymerization inhibitor may be added. By introducing a gas having a polymerization inhibiting effect into the reaction system or adding a polymerization inhibitor, gelation during the addition reaction can be prevented.

Examples of the gas having a polymerization inhibiting effect include a gas containing oxygen to an extent that it does not enter the explosion range of the substances in the system, for example, air.

As the polymerization inhibitor, known ones can be used and are not particularly limited, but examples include 4-methoxyphenol, hydroquinone, methoquinone, 2,6-di-t-butylphenol, 2,2′-methylenebis(4-methyl-6-t-butylphenol), phenothiazine, and the like. These polymerization inhibitors may be used as one kind only, or two or more kinds may be used in combination.

The amount of the polymerization inhibitor used is preferably 0.005 to 5 parts by mass, more preferably 0.03 to 3 parts by mass, and most preferably 0.05 to 1.5 parts by mass, with respect to 100 parts by mass of the total of the carboxy group-containing resin (b) and the alicyclic epoxy group-containing ethylenically unsaturated monomer (c). If the amount of the polymerization inhibitor is too small, the polymerization inhibiting effect may not be sufficient. On the other hand, if the amount of the polymerization inhibitor is too large, the exposure sensitivity of the resin (A) may decrease.

Furthermore, it is more preferable to use a gas having a polymerization inhibiting effect and a polymerization inhibitor in combination, since the amount of the polymerization inhibitor used can be reduced or the polymerization inhibiting effect can be enhanced.

The content of the resin (A) may be 70 mass % or more, 80 mass % or more, 90 mass % or more, 95 mass % or more, or 98 mass % or more, based on the total amount of the adhesive composition (total solid content of the adhesive composition excluding the solvent).

Examples of the photopolymerization initiator (B) include carbonyl-based photopolymerization initiators such as benzophenone, benzil, benzoin, ω-bromoacetophenone, chloroacetone, acetophenone, 2,2-diethoxyacetophenone, 2,2-dimethoxy-2-phenylacetophenone, p-dimethylaminoacetophenone, p-dimethylaminopropiophenone, 2-chlorobenzophenone, 4,4′-dichlorobenzophenone, 4,4′-bisdiethylaminobenzophenone, Michler's ketone, benzoin methyl ether, benzoin isobutyl ether, benzoin-n-butyl ether, benzyl methyl ketal, 1-hydroxycyclohexyl phenyl ketone, 2-hydroxy-2-methyl-1-phenyl-propan-1-one, 1-(4-isopropylphenyl)-2-hydroxy-2-methylpropan-1-one, methyl benzoylformate, 2,2-diethoxyacetophenone, 4-N,N′-dimethylacetophenone, and 2-methyl-1-[4-(methylthio)phenyl]-2-morpholinopropan-1-one.

Examples of the photopolymerization initiator (B) also include sulfide-based photopolymerization initiators such as diphenyldisulfide, dibenzyldisulfide, tetraethylthiuram disulfide, and tetramethylammonium monosulfide; acylphosphine oxides such as 2,4,6-trimethylbenzoyldiphenylphosphine oxide and 2,4,6-trimethylbenzoylphenylethoxyphosphine oxide; quinone-based photopolymerization initiators such as benzoquinone and anthraquinone; sulfochloride-based photopolymerization initiators; and thioxanthone-based photopolymerization initiators such as thioxanthone, 2-chlorothioxanthone, and 2-methylthioxanthone.

Among these photopolymerization initiators (B), it is preferable to use 1-hydroxycyclohexyl phenyl ketone and/or 2,4,6-trimethylbenzoyldiphenylphosphine oxide from the viewpoint of solubility in the adhesive composition. The photopolymerization initiator (B) may be used alone, or two or more kinds may be used in combination. The content of the photopolymerization initiator (B) is preferably 0.1 to 5.0 parts by mass, and more preferably 0.5 to 2.0 parts by mass, with respect to 100 parts by mass of the resin (A). When the content of the photopolymerization initiator (B) with respect to 100 parts by mass of the resin (A) is 0.1 parts by mass or more, the adhesive composition cures at a sufficiently fast curing speed by irradiation with activation energy, and the adhesive force of the adhesive composition after activation energy irradiation becomes sufficiently small, which is preferable. When the content of the photopolymerization initiator (B) is 5.0 parts by mass or less, the adhesive layer is less likely to remain on the adherend when the adhesive layer containing the adhesive composition is peeled off after being attached to the adherend.

The adhesive composition may include a cross-linking agent (C) in addition to the resin (A) and the photopolymerization initiator (B). By including the cross-linking agent (C), an adhesive composition with an even better balance between the adhesive force before activation energy irradiation and the adhesive force after activation energy irradiation is obtained.

The cross-linking agent (C) is not particularly limited, but a compound having two or more functional groups that are reactive with the hydroxyl group of the structural unit n, or the hydroxyl group of the structural unit n and the carboxy group of the structural unit m is preferable.

Examples of the cross-linking agent (C) include isocyanate-based compounds such as 2,4-tolylene diisocyanate, 2,6-tolylene diisocyanate, hydrogenated tolylene diisocyanate, 1,3-xylylene diisocyanate, 1,4-xylylene diisocyanate, diphenylmethane-4,4-diisocyanate, isophorone diisocyanate, 1,3-bis(N,N′-diglycidylaminomethyl)cyclohexane, 1,3-bis(isocyanatomethyl)cyclohexane, isocyanurate of hexamethylene diisocyanate, tetramethylxylylene diisocyanate, 1,5-naphthalene diisocyanate, tolylene diisocyanate adduct of trimethylolpropane, xylylene diisocyanate adduct of trimethylolpropane, triphenylmethane triisocyanate, and methylenebis(4-phenylmethane) triisocyanate; epoxy-based compounds such as bisphenol A/epichlorohydrin type epoxy resin, N,N′-[1,3-phenylenebis(methylene)]bis [bis(oxiran-2-ylmethyl) amine], ethylene glycol diglycidyl ether, polyethylene glycol diglycidyl ether, glycerin diglycidyl ether, glycerin triglycidyl ether, 1,6-hexanediol diglycidyl ether, trimethylolpropane triglycidyl ether, sorbitol polyglycidyl ether, polyglycerol polyglycidyl ether, pentaerythritol polyglycidyl erythritol, and diglycerol polyglycidyl ether; aziridine-based compounds such as tetramethylolmethane-tri-β-aziridinylpropionate, trimethylolpropane-tri-β-aziridinylpropionate, N,N′-diphenylmethane-4,4′-bis(1-aziridinecarboxamide), and N,N′-hexamethylene-1,6-bis(1-aziridinecarboxamide); and melamine-based compounds such as hexamethoxymethylmelamine, hexaethoxymethylmelamine, hexapropoxymethylmelamine, hexabutoxymethylmelamine, hexapentyloxymethylmelamine, and hexahexyloxymethylmelamine.

Among these, as the cross-linking agent (C), it is preferable to use an epoxy-based compound and/or an isocyanate-based compound because of their favorable reactivity with the resin (A). The cross-linking agent (C) may be used alone, or two or more kinds may be used in combination.

The content of the cross-linking agent (C) is preferably 0.05 to 10 parts by mass, more preferably 0.1 to 5 parts by mass, and even more preferably 0.1 to 1.0 part by mass, with respect to 100 parts by mass of the resin (A). When the content of the cross-linking agent (C) with respect to 100 parts by mass of the resin (A) is 0.05 parts by mass or more, a three-dimensional cross-linked structure is sufficiently formed in the adhesive composition. As a result, the adhesive force of the adhesive composition after activation energy irradiation becomes sufficiently small, which is preferable. When the content of the cross-linking agent (C) with respect to 100 parts by mass of the resin (A) is 10 parts by mass or less, the adhesive force of the adhesive composition before activation energy irradiation becomes sufficient.

The adhesive composition may contain other components other than the resin (A), the photopolymerization initiator (B), and the cross-linking agent (C), as necessary. Examples of other components include a tackifier, various additives, and the like.

As the tackifier, conventionally known ones can be used without particular limitation. Examples of the tackifier include terpene-based resins, phenol-based resins, rosin-based resins, aliphatic petroleum resins, aromatic petroleum resins, copolymer-based petroleum resins, alicyclic petroleum resins, xylene resins, epoxy-based resins, polyamide-based resins, ketone-based resins, elastomer-based resins, and the like. These tackifiers may be used alone, or two or more kinds may be used in combination.

When the adhesive composition includes a tackifier, its content is preferably 30 parts by mass or less, and more preferably 5 to 20 parts by mass, with respect to 100 parts by mass of the resin (A).

Examples of additives include plasticizers, surface lubricants, leveling agents, softeners, antioxidants, anti-aging agents, light stabilizers, ultraviolet absorbers, polymerization inhibitors, light stabilizers such as benzotriazole-based ones, phosphate ester-based and other flame retardants, and antistatic agents such as surfactants.

The adhesive composition can be used as a coating liquid (adhesive varnish) containing a solvent for applying the adhesive composition.

As the solvent, for example, organic solvents such as methyl ethyl ketone, methyl isobutyl ketone, acetone, ethyl acetate, n-propyl acetate, tetrahydrofuran, dioxane, cyclohexanone, n-hexane, toluene, xylene, n-propanol, and isopropanol can be used. These solvents may be used alone, or two or more kinds may be used as a mixture.

The adhesive composition can be manufactured by a conventionally known method. For example, it can be manufactured by mixing and stirring the resin (A) and the photopolymerization initiator (B), and, as necessary, the cross-linking agent (C), a tackifier, and various additives in a solvent using a conventionally known method.

The adhesive layer 2 can be manufactured, for example, by the method shown below. First, the above-mentioned adhesive composition is dissolved or dispersed in a solvent to prepare a coating liquid (adhesive varnish). Next, the coating liquid (adhesive varnish) is applied onto a base film and dried by heating to form an adhesive layer. As another method for manufacturing the adhesive layer, there is a method in which the coating liquid (adhesive varnish) is applied onto a release film and dried by heating to form an adhesive layer. Thereafter, the release film having the adhesive layer is placed on the base film with the adhesive layer side facing the base, and the adhesive layer is transferred (adhered) onto the base film.

As a method for applying the coating liquid (adhesive varnish) onto the base film (or release film), a known method can be used. Specifically, examples include a method of applying using a conventional coater, for example, a gravure roll coater, a reverse roll coater, a kiss roll coater, a dip roll coater, a bar coater, a knife coater, a spray coater, a comma coater, a direct coater, or the like.

The thickness of the adhesive layer 2 may be 1 to 100 μm, 2 to 80 μm, or 5 to 50 μm.

As shown in FIG. 2, the semiconductor chip C is pushed up by a push-up jig 42 to peel the semiconductor chip C from the adhesive layer 2, and the semiconductor chip C is picked up by suction with a suction collet 44. When the adhesive layer 2 is one whose adhesive force is reduced by activation energy irradiation, the adhesive layer 2 is irradiated with activation energy rays prior to pickup. The irradiation dose is, for example, 10 to 1000 mJ/cm², and may be 100 to 700 mJ/cm² or 200 to 500 mJ/cm².

According to the cleaning method of the present embodiment, by cleaning the semiconductor chips C on the adhesive film 5 with a chemical solution, it is possible to remove foreign matter adhering to the semiconductor chips C to a high degree, as compared with cleaning with water. Furthermore, according to the cleaning method of the present embodiment, it is possible to prevent the semiconductor chips from detaching from the surface of the adhesive film during the process of cleaning the semiconductor chips with a chemical solution. By using the highly cleaned semiconductor chips C, it is possible to manufacture a semiconductor device having excellent connection reliability. This cleaning method is also useful in that it can be efficiently performed in a semiconductor manufacturing process. That is, according to this cleaning method, since the high-level cleaning with a chemical solution is performed on the surface 5f of the adhesive film 5 and in a state where the dicing ring DR is attached to the adhesive film 5, it is possible to pick up the cleaned semiconductor chips C and directly subject the semiconductor chips C to the next step. The semiconductor chips C may be cleaned with pure water before and/or after cleaning with the chemical solution.

### <Method for Manufacturing a Semiconductor Device>

### First Embodiment

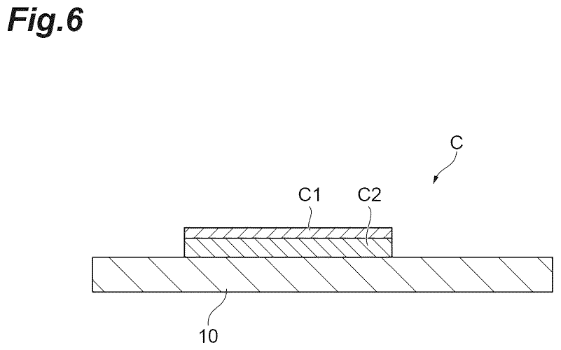

A method for manufacturing a semiconductor device including performing the above cleaning method will be specifically described. The method for manufacturing a semiconductor device according to the first embodiment includes the following steps.
(1a) Forming a photoresist Rp so as to cover a circuit layer Lc on a workpiece Pw including a semiconductor wafer W having a first surface f1 and a second surface f2, and the circuit layer Lc formed on the first surface f1 (see FIG. 3(a)).
(2a) Forming a groove G1 reaching the circuit layer Lc in the photoresist Rp by performing an exposure and development process on the photoresist Rp (see FIG. 3(b)).
(3a) Cutting the circuit layer Lc and half-cutting the semiconductor wafer W through the groove G1 by plasma dicing to form a groove G2 (see FIG. 3(c)).
(4a) Peeling off the photoresist Rp from the circuit layer Lc (see FIG. 4(a)).
(5a) Attaching a backgrind tape TBG so as to cover the circuit layer Lc (see FIG. 4(b)).
(6a) Obtaining a plurality of semiconductor chips C on a surface of the backgrind tape TBG by grinding the semiconductor wafer W from the second surface f2 side (see FIG. 4(c)).
(7a) Moving the plurality of semiconductor chips C from the surface of the backgrind tape TBG onto the surface 5f of the adhesive film 5, and attaching a dicing ring DR on the surface 5f so as to surround the plurality of semiconductor chips C (see FIG. 1).
(8a) Performing the method for cleaning semiconductor chips C.
(9a) Bonding the semiconductor chips C after cleaning to an adherend (see FIG. 6).

The workpiece Pw shown in FIG. 3(a) includes a semiconductor wafer W and a circuit layer Lc. The thickness of the semiconductor wafer W is, for example, 5 to 775 μm, and may be 50 to 300 μm. The diameter of the semiconductor wafer W is, for example, 50 to 300 mm, and may be 150 to 300 mm. Various electronic circuits (for example, integrated circuits and power supply circuits) are formed in the circuit layer Lc depending on the application of the semiconductor device. The thickness of the circuit layer Lc is, for example, 0.01 to 50 μm, and may be 0.1 to 10 μm. The photoresist Rp is composed of a photosensitive insulating material, and a groove G1 can be formed in the photoresist Rp by a photolithography process (FIG. 3(b)).

The groove G2 shown in FIG. 3(c) penetrates the circuit layer Lc and extends from the first surface f1 to the inside of the semiconductor wafer W. The groove G2 does not reach the second surface f2. The groove G2 is formed by plasma dicing. A process called the Bosch process is known as one type of plasma dicing. In the Bosch process, a passivation step using C4F8 plasma and an etching step using SF6 plasma are alternately performed to etch the silicon constituting the semiconductor wafer W. That is, in the passivation step, a fluorocarbon-based polymer film (hereinafter, simply referred to as “polymer film”) is isotropically formed on the entire inner surface of the groove G1. Thereafter, in the etching step, a bias is applied to the semiconductor wafer W, and the polymer film at the bottom of the groove G1 is removed by ion etching. On the other hand, the polymer film on the side wall of the groove G1 is not removed and constitutes the side wall of the groove G1. Only the silicon exposed at the bottom of the groove G1 from which the polymer film has been removed is etched by fluorine radicals. The groove G2 is formed by repeating these steps. The side surface of the groove G2 thus formed is covered with the polymer film. If the polymer film peels off in a subsequent process, it can become foreign matter that reduces the reliability of the semiconductor device. By dividing the circuit layer Lc by the groove G2, a plurality of circuit layers C1 are formed.

After the step (6a), the thickness of the die C2 (the thickness of the portion of the semiconductor chip C excluding the circuit layer C1) is, for example, 5 to 775 μm, and may be 50 to 300 μm. Grinding debris generated in the step (6a) can also become foreign matter that reduces the reliability of the semiconductor device.

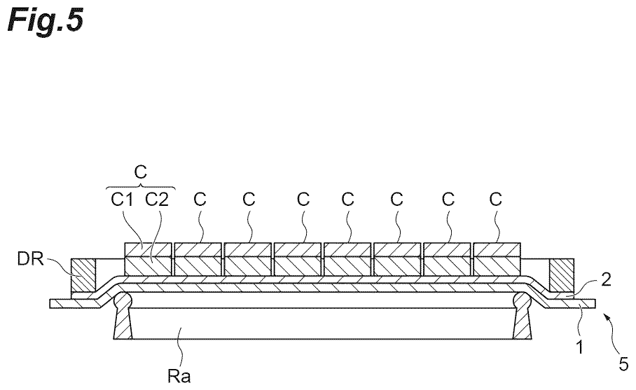

After the step (7a), prior to performing the method for cleaning the semiconductor chips C, the interval between two adjacent semiconductor chips C may be widened by applying tension to the adhesive film 5. That is, as shown in FIG. 5, tension is applied to the adhesive film 5 by pushing up the inside of the dicing ring DR with a ring Ra from the base film 1 side of the adhesive film 5. As a result, in the step (8a), the chemical solution is easily supplied to the side surfaces of the semiconductor chips C, and the polymer film adhering to the side surfaces can be sufficiently removed with the chemical solution. To remove the polymer film, it is preferable to use an HFE (hydrofluoroether)-based or an HAD (hydroxylamine)-based chemical solution as the chemical solution. On the other hand, to remove grinding debris, it is preferable to use the above-mentioned solvent-based, acid-based, or alkali-based chemical solution as the chemical solution.

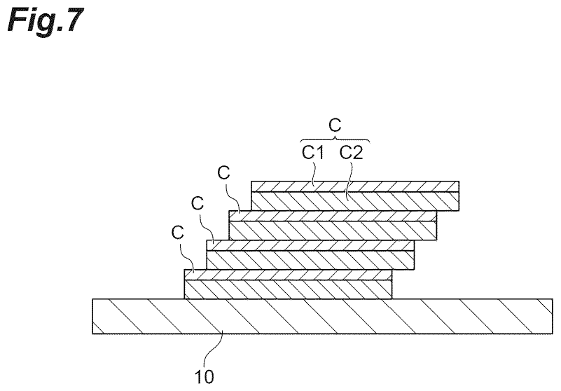

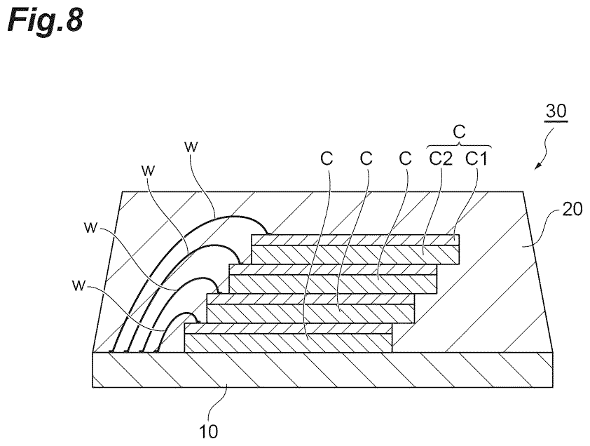

FIG. 6 is a cross-sectional view schematically showing a state in which a semiconductor chip C after cleaning is bonded to a substrate 10 (adherend). For bonding the semiconductor chip C to the substrate 10, for example, a die bonding film (not shown) is used. As shown in FIG. 7, when stacking a plurality of semiconductor chips C, the object (adherend) to which the semiconductor chips C of the second and subsequent stages are bonded is the lower semiconductor chip C. Through connecting the substrate 10 and the plurality of semiconductor chips C with wires w, respectively, and encapsulating the plurality of semiconductor chips C with a resin material 20, a semiconductor device 30 shown in FIG. 8 is manufactured.

### Second Embodiment

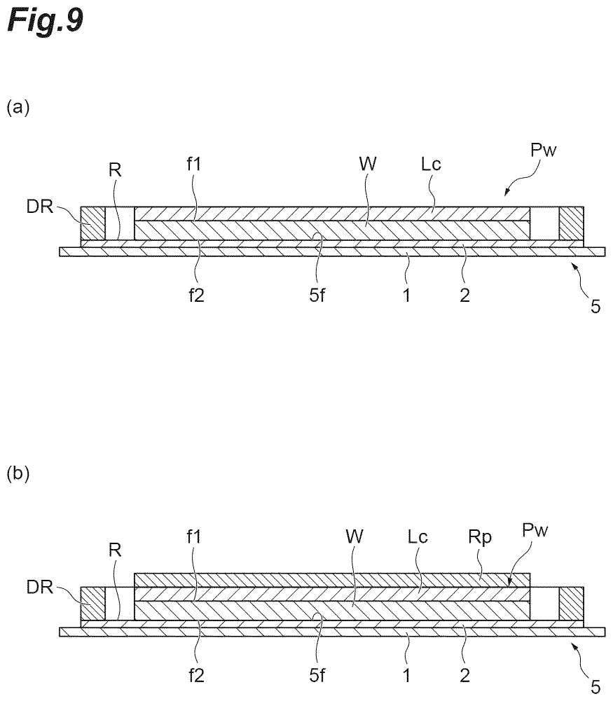

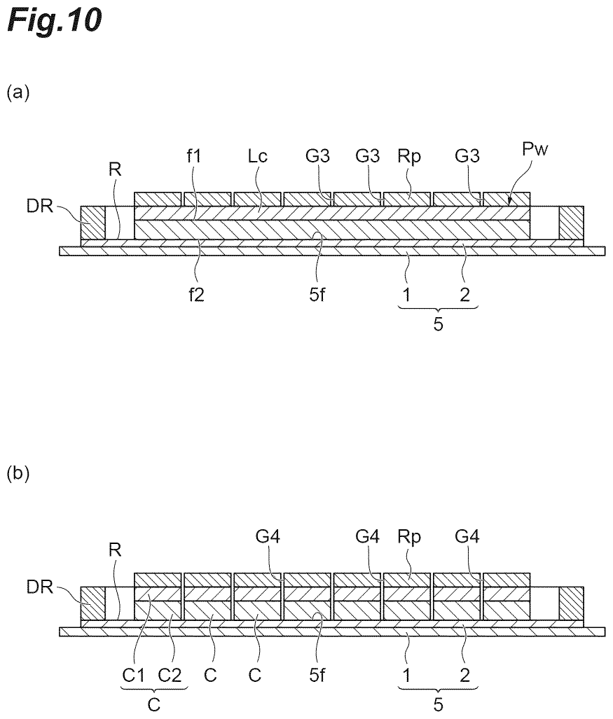

The method for manufacturing a semiconductor device according to the second embodiment includes the following steps.
(1b) Disposing a workpiece Pw in a region R within a dicing ring DR attached on a surface 5f of an adhesive film 5 (see FIG. 9(a)).
(2b) Forming a photoresist Rp so as to cover a circuit layer Lc (see FIG. 9(b)).
(3b) Forming a groove G3 reaching the circuit layer Lc in the photoresist by performing an exposure and development process on the photoresist Rp (see FIG. 10(a)).
(4b) Obtaining a plurality of semiconductor chips C on the surface 5f of the adhesive film 5 by cutting the circuit layer Lc and the semiconductor wafer W through the groove G3 by plasma dicing (see FIG. 10(b)).
(5b) Performing the method for cleaning semiconductor chips C (see FIGS. 1 and 2).
(6b) Bonding the semiconductor chips C after cleaning to an adherend (see FIG. 6).

This embodiment will be mainly described with respect to points different from the first embodiment. In this embodiment, the steps from (2b) to (5b) are performed on the surface of the adhesive film 5 to which the dicing ring DR is attached. After the step (4b), as shown in FIG. 10(b), the photoresist Rp remains on the upper surface of the semiconductor chip C. The photoresist Rp may be removed using a resist remover prior to performing the step (5b), or may be removed using a chemical solution in the step (5b). To remove the photoresist Rp, it is preferable to use a solvent-based chemical solution (particularly NMP). The groove G4 shown in FIG. 10(b) penetrates the circuit layer Lc and the semiconductor wafer W and reaches the surface 5f of the adhesive film 5. The groove G4 may be formed by plasma dicing, similar to the above-mentioned groove G2. The removal of the polymer film resulting from plasma dicing may be performed using an HFE-based or an HDA-based chemical solution, similar to the first embodiment.

### Third Embodiment

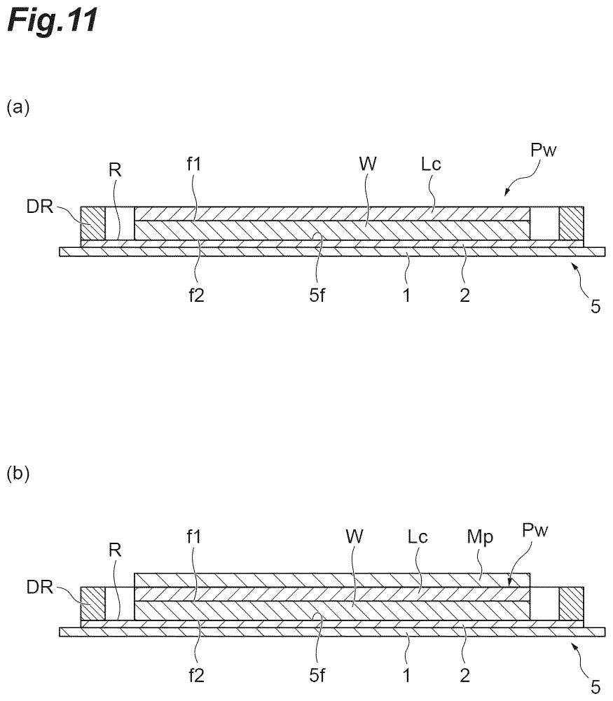

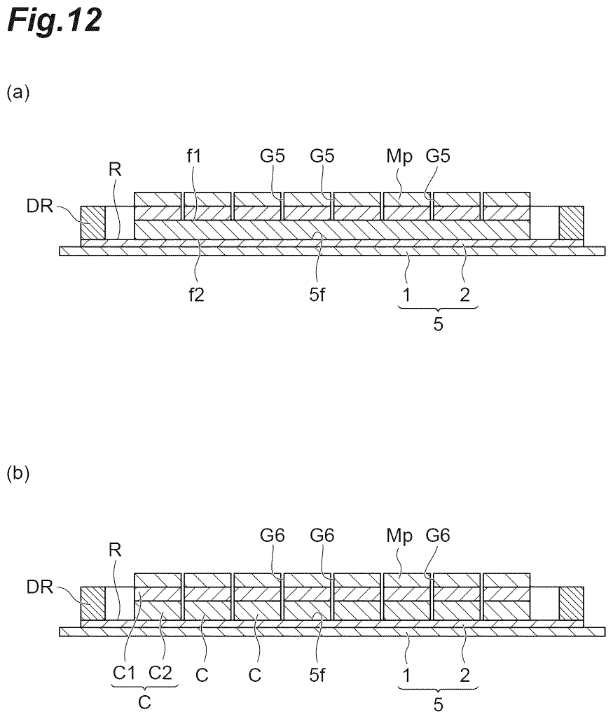

The method for manufacturing a semiconductor device according to the third embodiment includes the following steps.
(1c) Disposing a workpiece Pw in a region R within a dicing ring DR attached on a surface 5f of an adhesive film 5 (see FIG. 11(a)).
(2c) Forming a protective film Mp so as to cover a circuit layer Lc (see FIG. 11(b)).
(3c) Forming a groove G5 reaching the first surface f1 of the semiconductor wafer W by cutting the protective film Mp and the circuit layer Lc with a laser (see FIG. 12(a)).
(4c) Obtaining a plurality of semiconductor chips C on the surface 5f of the adhesive film 5 by cutting the semiconductor wafer W through the groove G5 by plasma dicing (see FIG. 12(b)).
(5c) Performing the method for cleaning semiconductor chips C (see FIGS. 1 and 2).
(6c) Bonding the semiconductor chips C after cleaning to an adherend (see FIG. 6).

This embodiment will be mainly described with respect to points different from the first and second embodiments. In this embodiment, a protective film Mp is formed in the step (2c). The protective film Mp is for preventing the circuit layer Lc from being damaged. The protective film Mp is composed of, for example, a water-soluble resin, and can be formed by applying a coating film including the resin onto the surface of the workpiece Pw. The protective film Mp remains on the upper surface of the semiconductor chip C after the step (4c) (see FIG. 12(b)). The protective film Mp is removed with pure water in the step (5c). The groove G6 shown in FIG. 12(b) penetrates the semiconductor wafer W and reaches the surface 5f of the adhesive film 5. The groove G6 may be formed by plasma dicing, similar to the above-mentioned groove G2. The removal of the polymer film resulting from plasma dicing may be performed using an HFE-based or an HDA-based chemical solution, similar to the first embodiment.

In this embodiment, the groove G6 may be formed by blade dicing instead of plasma dicing. For example, when the circuit layer Lc includes a low-k film, from the viewpoint of suppressing peeling of the low-k film, which has a relatively low mechanical strength, the circuit layer Lc is cut by a laser to form the groove G5. On the other hand, thereafter, the process of severing the semiconductor wafer W (the process of forming the groove G6) may be performed by blade dicing. The low-k film is a film composed of a material with a low dielectric constant, and is mainly used in the interconnect layer, that is, as an insulating material between the metal wirings that electrically connect different electronic components in a chip. By using a low-k film, the parasitic capacitance between wirings can be reduced, thereby improving the signal transmission speed and suppressing crosstalk between wirings. The process of forming a groove in the circuit layer Lc by a laser is called laser grooving.

### Fourth Embodiment

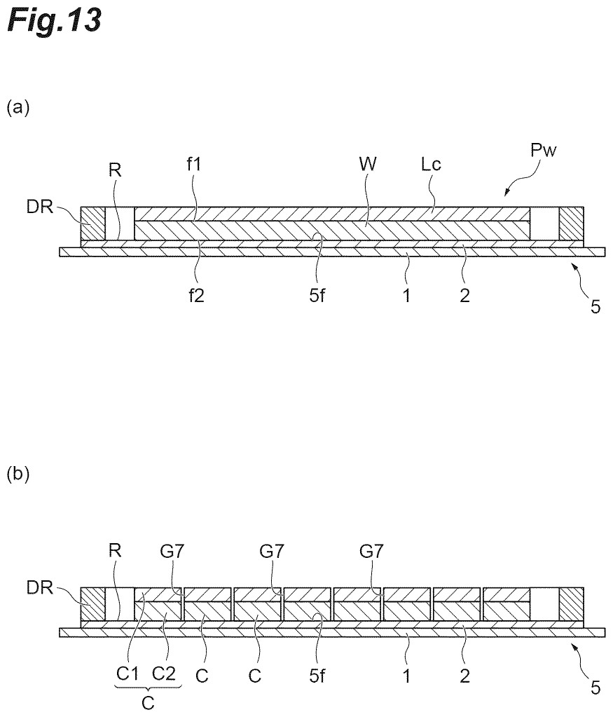

The method for manufacturing a semiconductor device according to the fourth embodiment includes the following steps.
(1d) Disposing a workpiece Pw in a region R within a dicing ring DR attached on a surface 5f of an adhesive film 5 (see FIG. 13(a)).
(2d) Obtaining a plurality of semiconductor chips C on the surface 5f of the adhesive film 5 by cutting the workpiece Pw by blade dicing (see FIG. 13(b)).
(3d) Performing the method for cleaning semiconductor chips C (see FIGS. 1 and 2).
(4d) Bonding the semiconductor chips C after cleaning to an adherend (see FIG. 6).

This embodiment will be mainly described with respect to points different from the first, second, and third embodiments. In this embodiment, in the step (2d), the workpiece Pw is singulated into a plurality of semiconductor chips C by blade dicing. The groove G7 formed by blade dicing penetrates the circuit layer Lc and the semiconductor wafer W and reaches the surface 5f of the adhesive film 5. Grinding debris generated in the step (2d) can become foreign matter that reduces the reliability of the semiconductor device. For removing the grinding debris generated by blade dicing, it is preferable to use the above-mentioned solvent-based, acid-based, or alkali-based chemical solution as the chemical solution. According to this embodiment, forming a photoresist or a protective film is unnecessary, and removing them is also unnecessary.

### Fifth Embodiment

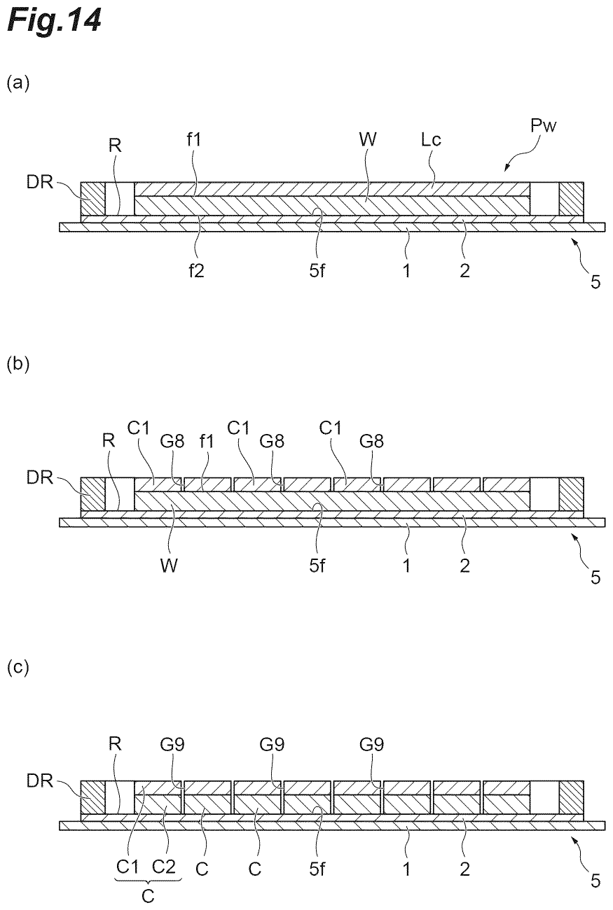

The method for manufacturing a semiconductor device according to the fifth embodiment includes the following steps.
(1e) Disposing a workpiece Pw in a region R within a dicing ring DR attached on a surface 5f of an adhesive film 5 (see FIG. 14(a)).
(2e) Forming a groove G8 reaching the first surface f1 of the semiconductor wafer W by cutting the circuit layer Lc with a laser (see FIG. 14(b)).
(3e) Obtaining a plurality of semiconductor chips C on the surface 5f of the adhesive film 5 by cutting the semiconductor wafer W through the groove G8 by blade dicing (see FIG. 14(c)).
(4e) Performing the method for cleaning semiconductor chips (see FIGS. 1 and 2).
(5e) Bonding the semiconductor chips C after cleaning to an adherend (see FIG. 6).

This embodiment will be mainly described with respect to points different from the fourth embodiment. In this embodiment, in the step (2e), the circuit layer Lc is cut by a laser. Since a laser is used to cut the circuit layer Lc, even if the circuit layer Lc includes a low-k film, peeling of the low-k film can be suppressed. Next, the semiconductor wafer W is severed by blade dicing. The groove G9 shown in FIG. 14(c) penetrates the semiconductor wafer W and reaches the surface 5f of the adhesive film 5. Grinding debris generated in the steps (2e) and (3e) can become foreign matter that reduces the reliability of the semiconductor device. According to this embodiment, the grinding debris generated in these steps can be removed in the subsequent step (4e). It is preferable to use the above-mentioned solvent-based, acid-based, or alkali-based chemical solution as the chemical solution.

Although the embodiments of the present disclosure have been described in detail above, the present disclosure is not limited to the above embodiments. For example, in the second, third, fourth, and fifth embodiments, an aspect in which the semiconductor wafer W is used as is without backgrinding has been exemplified, but the semiconductor wafer W may be backgrinded prior to disposing the semiconductor wafer W in the region R of the adhesive film 5. That is, in the above-described predetermined embodiments, before disposing the workpiece Pw in the region R of the adhesive film 5, the semiconductor wafer W may be ground from the second surface f2 side in a state where a backgrind tape is attached to the workpiece Pw so as to cover the circuit layer Lc. In this case as well, the circuit layer Lc may include a low-k film.

### REFERENCE SIGNS LIST

1 . . . base film, 2 . . . adhesive layer, 5 . . . adhesive film, 5f . . . surface of adhesive film, 10 . . . substrate (adherend), 20 . . . resin material, 30 . . . semiconductor device, 42 . . . push-up jig, 44 . . . suction collet, C . . . semiconductor chip, C1 . . . (singulated) circuit layer, C2 . . . die, DR . . . dicing ring, f1 . . . first surface, f2 . . . second surface, G1, G2, G3, G4, G5, G6, G7, G8, G9 . . . groove, Lc . . . circuit layer, Mp . . . protective film, Pw . . . workpiece, R . . . region, Rp . . . photoresist, TBG . . . backgrind tape, W . . . semiconductor wafer, w . . . wire.

1. A method for cleaning semiconductor chips, the method comprising:
(a) cleaning, with a chemical solution, a plurality of semiconductor chips disposed in a region on a surface of an adhesive film, wherein the region is within a dicing ring attached on the surface; and
(b) picking up the semiconductor chips from the surface after the cleaning, wherein the adhesive film comprises a base film and an adhesive layer formed on a surface of the base film,
wherein the adhesive layer comprises an adhesive composition comprising a resin (A) represented by the following formula (1-1) and a photopolymerization initiator (B): 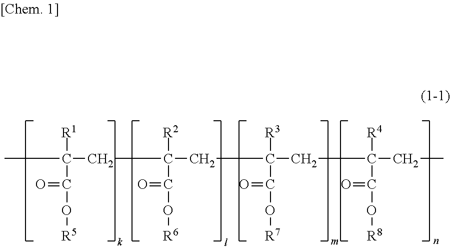
wherein in formula (1-1), k, 1, m, and n represent a molar composition ratio when k+1+m+n=100, k is more than 0 and 92 or less, 1 is from 0 to 50, m is more than 0 and 90 or less, a total of k, 1, and m is from 65 to 95, n is from 5 to 35, R¹, R², R³, and R⁴ are a hydrogen atom or a methyl group, R⁵ is an alkyl group having 1 to 16 carbon atoms, R⁶ is an alicyclic hydrocarbon group having 3 to 30 carbon atoms or an aromatic hydrocarbon group having 6 to 20 carbon atoms, R⁷ is a hydrogen atom or —(CH₂)ⱼ—COOH (wherein j is 1 or 2), and R⁸ is a group represented by the following formula (1-2) or the following formula (1-3): 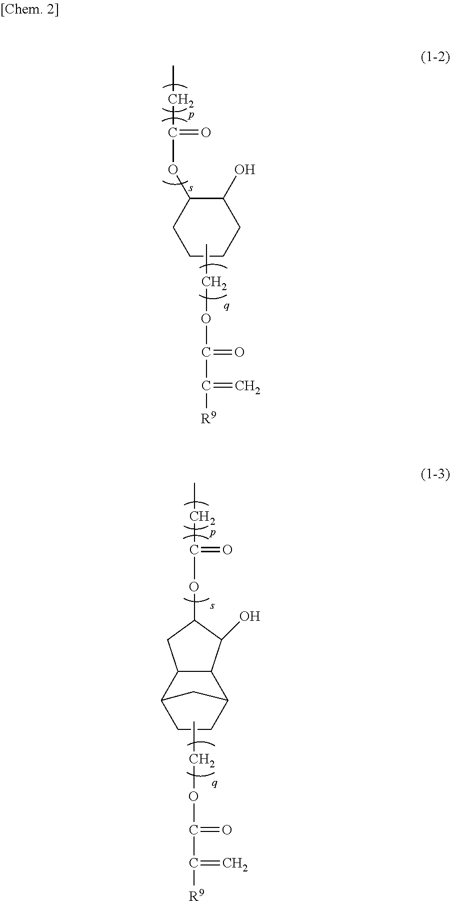
wherein in formula (1-2) and formula (1-3), p and q are an integer from 0 to 2, s is 0 when p is 0, and s is 1 when p is 1 or 2, and R9 is a hydrogen atom or a methyl group, and
wherein the chemical solution is a chemical solution selected from the group consisting of solvent-based, acid-based, and alkali-based chemical solutions.

2. A method for manufacturing a semiconductor device, comprising performing the method according to claim 1,
wherein the method for manufacturing a semiconductor device comprises:
forming a photoresist on a workpiece so as to cover a circuit layer, the workpiece comprising a semiconductor wafer having a first surface and a second surface, and the circuit layer formed on the first surface;
forming a groove reaching the circuit layer in the photoresist by performing an exposure and development process on the photoresist;
cutting the circuit layer and half-cutting the semiconductor wafer through the groove by plasma dicing;
peeling off the photoresist from the circuit layer;
attaching a backgrind tape so as to cover the circuit layer;
obtaining a plurality of semiconductor chips on a surface of the backgrind tape by grinding the semiconductor wafer from a side of the second surface;
moving the plurality of semiconductor chips from the surface of the backgrind tape onto the surface of the adhesive film, and attaching a dicing ring on the surface of the adhesive film so as to surround the plurality of semiconductor chips;
performing the method according to claim 1; and
bonding the semiconductor chips after the cleaning to an adherend.

3. A method for manufacturing a semiconductor device, comprising performing the method according to claim 1,
wherein the method for manufacturing a semiconductor device comprises:
disposing a workpiece in a region on a surface of the adhesive film, the region being within a dicing ring attached on the surface, the workpiece comprising a semiconductor wafer having a first surface and a second surface, and a circuit layer formed on the first surface;
forming a photoresist so as to cover the circuit layer;
forming a groove reaching the circuit layer in the photoresist by performing an exposure and development process on the photoresist;
obtaining a plurality of semiconductor chips on the surface of the adhesive film by cutting the circuit layer and the semiconductor wafer through the groove by plasma dicing;
performing the method according to claim 1; and
bonding the semiconductor chips after the cleaning to an adherend.

4. A method for manufacturing a semiconductor device, comprising performing the method according to claim 1,
wherein the method for manufacturing a semiconductor device comprises:
disposing a workpiece in a region on a surface of the adhesive film, the region being within a dicing ring attached on the surface, the workpiece comprising a semiconductor wafer having a first surface and a second surface, and a circuit layer formed on the first surface;
forming a protective film so as to cover the circuit layer;
forming a groove reaching the first surface by cutting the protective film and the circuit layer with a laser;
obtaining a plurality of semiconductor chips on the surface of the adhesive film by cutting the semiconductor wafer through the groove by plasma dicing;
performing the method according to claim 1; and
bonding the semiconductor chips after the cleaning to an adherend.

5. The method for manufacturing a semiconductor device according to claim 4, wherein the cleaning of (a) removes the protective film.

6. A method for manufacturing a semiconductor device, comprising performing the method according to claim 1,
wherein the method for manufacturing a semiconductor device comprises:
disposing a workpiece in a region on a surface of the adhesive film, the region being within a dicing ring attached on the surface, the workpiece comprising a semiconductor wafer having a first surface and a second surface, and a circuit layer formed on the first surface;
obtaining a plurality of semiconductor chips on the surface of the adhesive film by cutting the workpiece by blade dicing;
performing the method according to claim 1; and
bonding the semiconductor chips after the cleaning to an adherend.

7. A method for manufacturing a semiconductor device, comprising performing the method according to claim 1,
wherein the method for manufacturing a semiconductor device comprises:
disposing a workpiece in a region on a surface of the adhesive film, the region being within a dicing ring attached on the surface, the workpiece comprising a semiconductor wafer having a first surface and a second surface, and a circuit layer formed on the first surface;
dividing the circuit layer into a plurality of singulated circuit layers by forming a groove in the circuit layer with a laser;
obtaining a plurality of semiconductor chips on the surface of the adhesive film by cutting the semiconductor wafer through the groove by blade dicing;
performing the method according to claim 1; and
bonding the semiconductor chips after the cleaning to an adherend.

8. A method for manufacturing a semiconductor device, comprising performing the method according to claim 1,
wherein the method for manufacturing a semiconductor device comprises:
disposing a workpiece in a region on a surface of the adhesive film, the region being within a dicing ring attached on the surface, the workpiece comprising a semiconductor wafer having a first surface and a second surface, and a circuit layer formed on the first surface;
forming a protective film so as to cover the circuit layer;
forming a groove reaching the first surface by cutting the protective film and the circuit layer with a laser;
obtaining a plurality of semiconductor chips on the surface of the adhesive film by cutting the semiconductor wafer through the groove by blade dicing;
performing the method according to claim 1; and
bonding the semiconductor chips after the cleaning to an adherend.

9. The method for manufacturing a semiconductor device according to claim 8, wherein the cleaning of (a) removes the protective film.

10. The method for manufacturing a semiconductor device according to claim 7, wherein the circuit layer formed on the first surface of the semiconductor wafer comprises a low-k film.

11. The method for manufacturing a semiconductor device according to 9 claim 3, further comprising, before disposing the workpiece in the region on the surface of the adhesive film, grinding the semiconductor wafer from a side of the second surface in a state where a backgrind tape is attached to the workpiece so as to cover the circuit layer.

12. The method of claim 1, wherein the adhesive composition further comprises a cross-linking agent (C).

13. The method for manufacturing a semiconductor device according to claim 8, wherein the circuit layer formed on the first surface of the semiconductor wafer comprises a low-k film.

14. The method for manufacturing a semiconductor device according to claim 9, wherein the circuit layer formed on the first surface of the semiconductor wafer comprises a low-k film.

15. The method for manufacturing a semiconductor device according to claim 4, further comprising, before disposing the workpiece in the region on the surface of the adhesive film, grinding the semiconductor wafer from a side of the second surface in a state where a backgrind tape is attached to the workpiece so as to cover the circuit layer.

16. The method for manufacturing a semiconductor device according to claim 6, further comprising, before disposing the workpiece in the region on the surface of the adhesive film, grinding the semiconductor wafer from a side of the second surface in a state where a backgrind tape is attached to the workpiece so as to cover the circuit layer.

17. The method for manufacturing a semiconductor device according to claim 7, further comprising, before disposing the workpiece in the region on the surface of the adhesive film, grinding the semiconductor wafer from a side of the second surface in a state where a backgrind tape is attached to the workpiece so as to cover the circuit layer.

18. The method for manufacturing a semiconductor device according to claim 8, further comprising, before disposing the workpiece in the region on the surface of the adhesive film, grinding the semiconductor wafer from a side of the second surface in a state where a backgrind tape is attached to the workpiece so as to cover the circuit layer.
